(19) United States
(12) Patent Application Publication
(10) Pub. No.: US 2010/0157716 A1
(43) Pub. Date: Jun. 24, 2010

(54) Sub word line driving circuit

(75) Inventor: Jong Won Lee, Gwangmyeong-si (KR)

Correspondence Address: COOPER & DUNHAM, LLP, 30 Rockefeller Plaza, 20th Floor, NEW YORK, NY, 10112, US

(73) Assignee: Hynix Semiconductor Inc.

(21) Appl. No.: 12/455,749

(22) Filed: Jun. 5, 2009

(30) Foreign Application Priority Data
Dec. 23, 2008 (KR) 10-2008-0132698

(51) Int. Cl. G11C 8/08; G11C 7/00

(52) U.S. Cl. 365/230.06; 365/203

(57) ABSTRACT

A sub word line driving circuit includes a FX driver which buffers an inverted FX signal to generate a FX signal in response to a control signal, and a sub word line driver which is supplied with the FX signal and receives a main word line signal to drive a sub word line signal.

### TECHNICAL FIELD

This disclosure relates to a semiconductor memory device, and more particularly, to a sub word line driving circuit capable of reducing leakage current in a standby state.

### BACKGROUND

FIG. 1 is a view showing a configuration of a conventional semiconductor memory device and FIG. 2 is a circuit diagram of a sub word line driving circuit including a FX driver and a sub word line driver.

As shown in FIG. 1, a semiconductor memory device includes a plurality of FX drivers FX DRIVER<1:m> placed between bit line sense amplifier arrays BLSA ARRAY and a plurality of sub word line drivers SUB <1,1:n,m> placed between memory cell arrays MEMORY CELL ARRAY. A structure of a sub word line driving circuit including the FX driver FX DRIVER<m> which generates a FX signal FX<m> and the sub word line driver SUBWL DRIVER<n,m> which receives the FX signal FX<m> and an inverted main word line signal MWLB<n> and generates a sub word line signal SWL<n,m>, among the plurality of FX drivers FX DRIVER<1:m> and the plurality of sub word line drivers SUB WL DRIVER<1:n, 1:m>, will be described more detail.

Referring to FIG. 2, a conventional sub word line driving circuit includes a FX driver 10 and a sub word line driver 12. The FX driver 10 inverts and buffers an inverted FX signal FXB<m> to generate the FX signal FX<m>. Also, the sub word line driver 12 is driven by receiving the FX signal FX<m> as a power signal to invert and buffer the inverted main word line signal MWLB<n> and generate the sub word line signal SWL<n,m>. The sub word line driving circuit configured as described above decodes a row address and generates the sub word line signal SWL<n,m> enabled to a high level when the inverted FX signal FXB<m> and the inverted main word line signal MWLB<n> are enabled to a low level.

Meanwhile, in a standby state, since a plurality of inverted FX signals FXB<1:m> and a plurality of inverted main word line signals MWLB<1:n> are all maintained at a high level (a high voltage level of about 3.3V), the plurality of the sub word line signals SWL<1:n,1:m> are all maintained at a low level. In this standby state, a problem of Gate Induced Drain Leakage (GIDL) can be raised. That is to say, in case of MOS transistors included in the conventional sub word line driving circuit, as they have reduced sizes and are highly doped, GIDL or a leakage current I1 which flows from a PMOS transistor P11 towards an NMOS transistor N10 and GIDL or a leakage current I2 which flows from the PMOS transistor P11 to an NMOS transistor N11 and an NMOS transistor N12 are generated in a standby state in which a ground voltage is applied to a source and a drain. As such, in the case of the conventional sub word line driving circuit, a leakage current corresponding to two times of that of a general CMOS inverter type gate is generated since two current paths of the GIDL are present.

### SUMMARY

In an aspect of this disclosure, there is provided a sub word line driving circuit capable of reducing a leakage current in a standby state by controlling GIDL flowing to a FX driver using a bit line equalizing signal.

In one embodiment, a sub word line driving circuit includes a FX driver which buffers an inverted FX signal and generates a FX signal in response to a control signal, and a sub word line driver which is supplied with the FX signal and receives a main word line signal to drive a sub word line signal.

In another embodiment, a sub word line driving circuit includes a FX driver which buffers an inverted FX signal and generates a FX signal in response to a control signal, and a sub word line driver which is supplied with the FX signal and receives a main word line signal to drive a sub word line signal in response to the control signal.

In another embodiment, a sub word line driving circuit includes a first FX driver which is connected to a first node, buffers a first inverted FX signal and generates a first FX signal, a second FX driver which is connected to the first node, buffers a second inverted FX signal and generates a second FX signal, a first switching unit which is connected between the first node and a ground voltage and is turned on in response to a control signal, a first sub word line driver which is supplied with the first FX signal and receives a main word line signal to drive a first sub word line signal, and a second sub word line driver which is supplied with the second FX signal and receives a main word line signal to drive a second sub word line signal.

### BRIEF DESCRIPTION OF THE DRAWINGS

The above and other aspects, features and other advantages will be more clearly understood from the following detailed description taken in conjunction with the accompanying drawings, in which:

FIG. 1 is a view showing a configuration of a conventional semiconductor memory device;

FIG. 2 is a circuit diagram of a sub word line driving circuit including a FX driver and a sub word line driver;

FIG. 3 is a circuit diagram illustrating a sub word line driving circuit in accordance with an embodiment of the present invention;

FIG. 4 is a diagram illustrating an operation of the sub word line driving circuit shown in FIG. 3;

FIG. 5 is a circuit diagram illustrating a sub word line driving circuit in accordance with another embodiment of the present invention; and

FIG. 6 is a circuit diagram illustrating a sub word line driving circuit in accordance with another embodiment of the present invention.

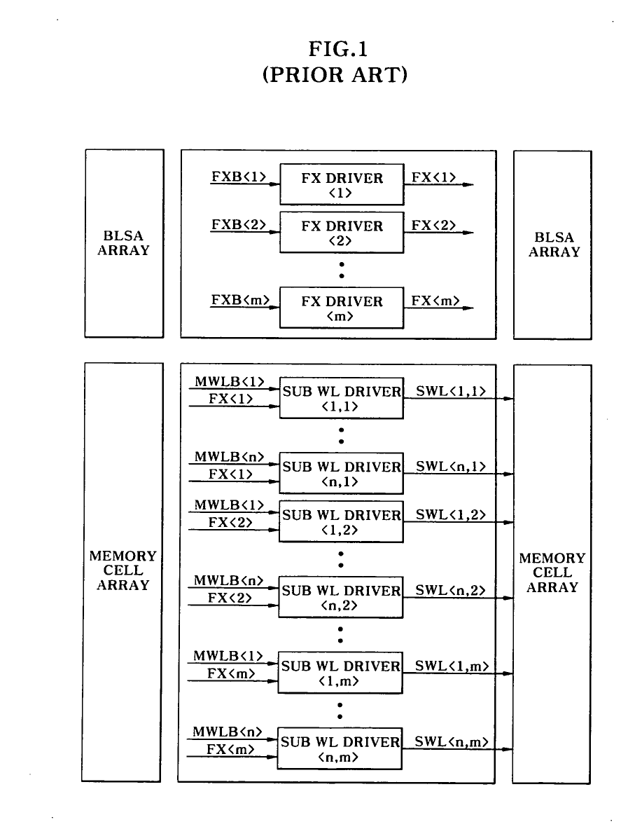

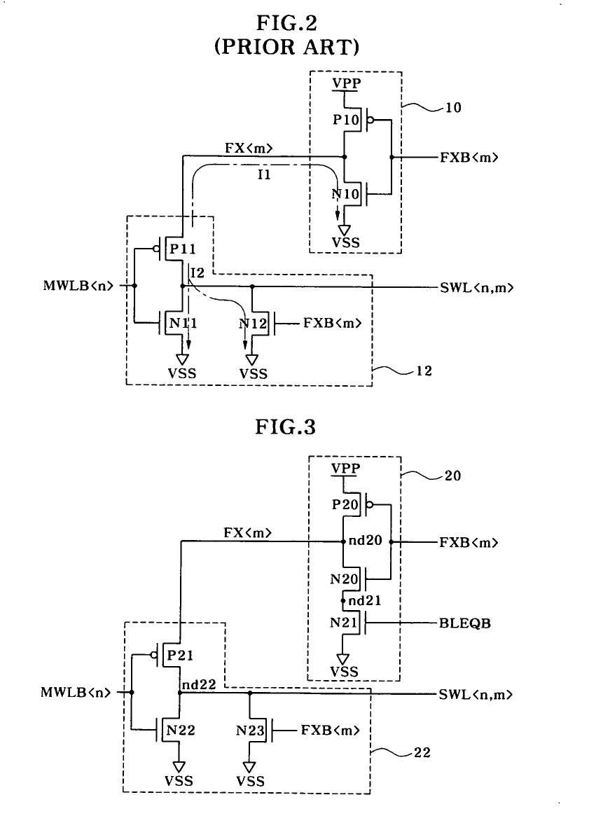

### DESCRIPTION OF PREFERRED EMBODIMENTS

Hereinafter, embodiments of the present invention will be described with reference to accompanying drawings. However, the embodiments are for illustrative purposes only and are not intend to limit the scope of the invention.

FIG. 3 is a circuit diagram illustrating a sub word line driving circuit in accordance with an embodiment of the present invention.

As shown in FIG. 3, a sub word line driving circuit in accordance with the present embodiment includes a first FX driver 20 and a first sub word line driver 22.

The first FX driver 20 includes a PMOS transistor P20 which is connected between a high voltage VPP and a node nd20 and operates as a pull-up device pull-up driving the node nd20 in response to an inverted FX signal FXB<m>, an NMOS transistor N20 which is connected between the node nd20 and a node nd21 and operates as a pull-down device pull-down driving the node nd20 in response to the inverted FX signal FXB<m> and an NMOS transistor N21 which is connected between the node nd21 and a ground voltage VSS and operates as a switching device turned on in response to an inverted bit line equalizing signal BLEQB. The inverted bit line equalizing signal BLEQB is a signal enabled to a low level to supply a bit line precharge voltage VBLP to a bit line pair BL, BLB in a standby state. The FX signal FX<m> is outputted through the node nd20.

The first sub word line driver 22 includes a PMOS transistor P21 which is connected between the node nd20 and the node nd22 and operates as a pull-up device pull-up driving the node nd22 in response to an inverted main word line signal MWLB<n>, an NMOS transistor N22 which is connected between the node nd22 and a ground voltage VSS and operates as a pull-down device pull-down driving the node nd22 in response to the inverted main word line signal MWLB<n> and an NMOS transistor N23 which is connected between the node nd22 and a ground voltage VSS and operates as a pull-down device pull-down driving the node nd22 in response to the FX signal FX<m>. A sub word line signal SWL<n,m> is outputted through the node nd22.

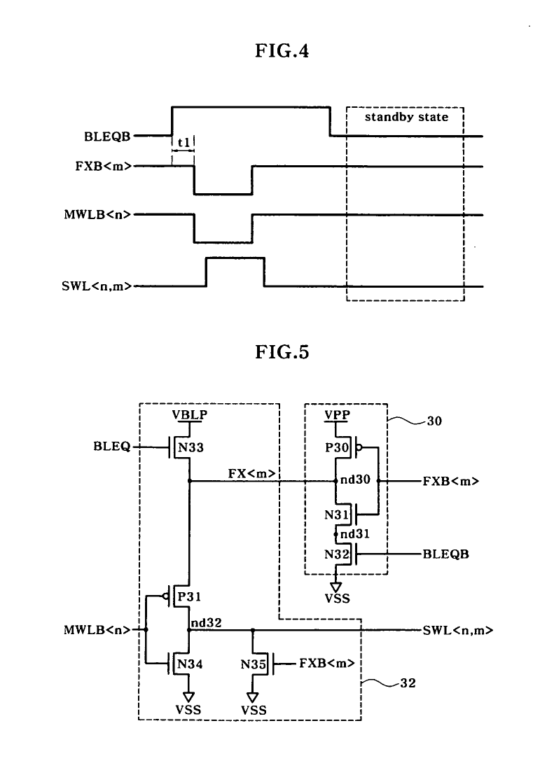

An operation of the sub word line driving circuit configured as described above will be described with reference to FIG. 4.

As shown in FIG. 4, when the inverted FX signal FXB<m> and the inverted main word line signal MWLB<n> are enabled to a low level by decoding the row address, the first FX driver 20 receives the inverted FX signal FXB<m> and drives the FX signal FX<m> to a high level, and the first sub word line driver 22 drives the sub word line signal SWL<n,m> to a high level. At this time, since the inverted bit line equalizing signal BLEQB is at a high level, the NMOS transistor N21 is turned on to drive the node nd21 to the ground voltage VSS.

Next, when the inverted FX signal FXB<m> and the inverted main word line signal MWLB<n> are shifted to a high level and a certain period is elapsed, the circuit enters into the standby state. In the standby state, the NMOS transistor N21 is turned off since the inverted bit line equalizing signal BLEQB is at a low level. Therefore, the FX signal is not driven to the ground voltage VSS even when the NMOS transistor N20 is turned on by the inverted FX signal FXB<m> at a high level. That is to say, the node nd20 through which the FX signal FX<m> is outputted becomes a floating state and the node nd20 comes to have a raised level by a leakage current flowing through the PMOS transistor P21. Therefore, a voltage difference between gate and source of the PMOS transistor P21 is reduced and a leakage current flowing from the PMOS transistor P21 to the NMOS transistor N20, or GIDL is reduced.

Meanwhile, since the inverted bit line equalizing signal BLEQB is shifted to a high level to turn on the NMOS transistor N21 a t1 period before the inverted FX signal FXB<m> and the inverted main word line signal MWLB<n> are enabled again to a low level, the node nd21 is driven to the ground voltage VSS. The reason of driving the node nd21 to the ground voltage VSS is for allowing the sub word line signal SWL<n,m> to be sufficiently driven.

As such, the sub word line driving circuit in accordance with the present embodiment reduces the GIDL in the standby state by setting the node nd20 to a level higher than the ground voltage VSS by the inverted bit line equalizing signal BLEQB, and allows the sub word line signal SWL<n,m> to be sufficiently driven by driving the node nd21 to the ground voltage VSS by the inverted bit line equalizing signal BLEQB before the inverted FX signal FXB<m> and the inverted main word line signal MWLB<n> are enabled to a low level.

FIG. 5 is a circuit diagram illustrating a sub word line driving circuit in accordance with another embodiment of the present invention.

As shown in FIG. 5, a sub word line driving circuit in accordance with the present embodiment includes a second FX driver 30 and a second sub word line driver 32.

The second FX driver 30 includes a PMOS transistor P30 which is connected between a high voltage VPP and a node nd30 and operates as a pull-up device pull-up driving the node nd30 in response to the inverted FX signal FXB<m>, an NMOS transistor N31 which is connected between the node nd30 and a node nd31 and operates as a pull-down device pull-down driving the node nd30 in response to the inverted FX signal FXB<m> and an NMOS transistor N32 which is connected between the node nd31 and a ground voltage VSS and operates as a switching device turned on in response to the inverted bit line equalizing signal BLEQB. The FX signal FX<m> is outputted through the node nd30.

The second sub word line driver 32 includes an NMOS transistor N33 which is connected between the bit line precharge voltage VBLP and the node nd30 and operates as a switching device turned on in response to a bit line equalizing signal BLEQ, a PMOS transistor P31 which is connected between the node nd30 and a node nd32 and operates as a pull-up device pull-up driving the node nd32 in response to the inverted main word line signal MWLB<n>, an NMOS transistor N34 which is connected between the node nd32 and the ground voltage VSS and operates as a pull-down device pull-down driving the node nd32 in response to the inverted main word line signal MWLB<n> and an NMOS transistor N35 which is connected between the node nd32 and the ground voltage VSS and operates as a pull-down device pull-down driving the node nd32 in response to the inverted FX signal FXB<m>. A sub word line signal SWL<n,m> is outputted through the node nd32.

An operation of the sub word line driving circuit configured as described above will be described.

When the inverted FX signal FXB<m> and the inverted main word line signal MWLB<n> are enabled to a low level by decoding the row address, the second FX driver 30 receives the inverted FX signal FXB<m> and drives the FX signal FX<m> to a high level, and the second sub word line driver 32 drives the sub word line signal SWL<n,m> to a high level. At this time, since the inverted bit line equalizing signal BLEQB is at a high level and the bit line equalizing signal BLEQ is at a low level, the NMOS transistor N32 is turned on to drive the node nd31 to the ground voltage VSS and the NMOS transistor N33 is turned off.

Next, when the inverted FX signal FXB<m> and the inverted main word line signal MWLB<n> are shifted to a high level and a certain period is elapsed, the circuit is entered into the standby state. In the standby state, the NMOS transistor N32 is turned off since the inverted bit line equalizing signal BLEQB is at a low level. Therefore, the FX signal FX<m> is not driven to the ground voltage VSS even when the NMOS transistor N31 is turned on by the inverted FX signal FXB<m> at a high level. That is to say, the node nd30 through which the FX signal FX<m> is outputted comes to have a raised level by a leakage current flowing through the PMOS transistor P31. Also, the NMOS transistor N33 is turned on to drive the node nd30 to the bit line precharge voltage VBLP since the bit line equalizing signal BLEQ is at a high level in the standby state. Therefore, a voltage difference between gate and source of the PMOS transistor P31 is reduced and a leakage current flowing from the PMOS transistor P31 to the NMOS transistor N31, or GIDL is reduced.

Meanwhile, the inverted bit line equalizing signal BLEQB is shifted to a high level to turn off the NMOS transistor N32 a t1 period before the inverted FX signal FXB<m> and the inverted main word line signal MWLB<n> are enabled again to a low level. Therefore, the node nd31 is driven to the ground voltage VSS to allow the sub word line signal SWL<n,m> to be sufficiently driven. At this time, the NMOS transistor N33 is turned off by the bit line equalizing signal BLEQ at a low level.

As such, the sub word line driving circuit in accordance with the present embodiment reduces the GIDL in the standby state by setting the node nd30 to a level higher than the ground voltage VSS by the inverted bit line equalizing signal BLEQB and the bit line equalizing signal BLEQ, and allows the sub word line signal SWL<n,m> to be sufficiently driven by driving the node nd31 to the ground voltage VSS by the inverted bit line equalizing signal BLEQB before the inverted FX signal FXB<m> and the inverted main word line signal MWLB<n> are enabled to a low level.

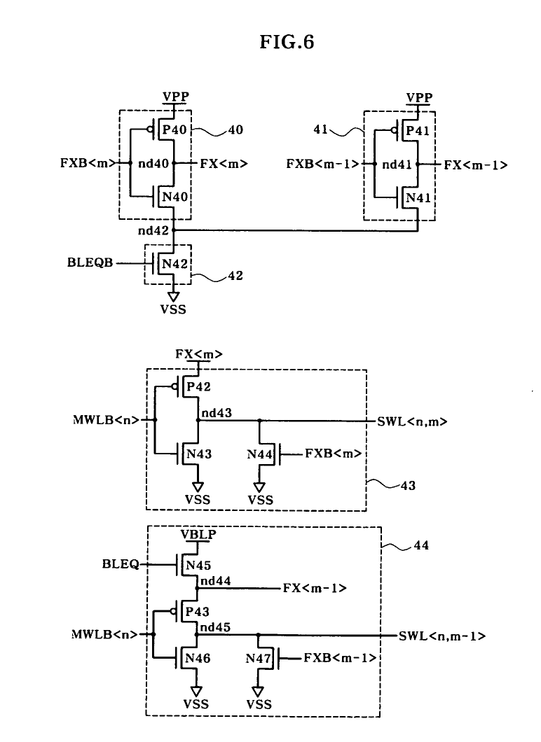

FIG. 6 is a circuit diagram illustrating a sub word line driving circuit in accordance with another embodiment of the present invention.

As shown in FIG. 6, a sub word line driving circuit in accordance with the present embodiment includes a third FX driver 40, a fourth FX driver 41, a switching unit 42, a third sub word line driver 43 and a fourth sub word line driver 44.

The third FX driver 40 includes a PMOS transistor P40 which is connected between a high voltage VPP and a node nd40 and operates as a pull-up device pull-up driving the node nd40 in response to a first inverted FX signal FXB<m>, and an NMOS transistor N40 which is connected between the node nd40 and a node nd42 and operates as a pull-down device pull-down driving the node nd40 in response to the first inverted FX signal FXB<m>.

The fourth FX driver 41 is a PMOS transistor P41 which is connected between the high voltage VPP and a node nd41 and operates as a pull-up device pull-up driving the node nd41 in response to a second inverted FX signal FXB<m-1>, and an NMOS transistor N41 which is connected between the node nd41 and the node nd42 and operates as a pull-down device pull-down driving the node nd41 in response to the second inverted FX signal FXB<m-1>.

The switching unit 42 includes an NMOS transistor N42 which is connected between the node nd42 and a ground voltage VSS and is turned on in response to the inverted bit line equalizing signal BLEQB.

The third sub word line driver 43 includes a PMOS transistor P42 which is connected between an input node for the first inverted FX signal FXB<m> and a node nd43 and operates as a pull-up device pull-up driving the node nd43 in response to the inverted main word line signal MWLB<n>, an NMOS transistor N43 which is connected between the node nd43 and the ground voltage VSS and operates as a pull-down device pull-down driving the node nd43 in response to the inverted main word line signal MWLB<n>, and an NMOS transistor N44 which is connected between the node nd43 and the ground voltage VSS and operates as a pull-down device pull-down driving the node nd43 in response to the first inverted FX signal FXB<m>. A first sub word line signal SWL<n,m> is outputted through the node nd43.

The fourth sub word line driver 44 includes an NMOS transistor N45 which is connected between a bit line precharge voltage VBLP and a node nd44 and operates as a switching device turned on in response to the bit line equalizing signal BLEQ, a PMOS transistor P43 which is connected between the node nd44 and the node nd45 and operates as a pull-up device pull-up driving the node nd45 in response to the inverted main word line signal MWLB<n>, an NMOS transistor N46 which is connected between the node nd45 and the ground voltage VSS and operates as a pull-down device pull-down driving the node nd45 in response to the inverted main word line signal MWLB<n>, and an NMOS transistor N47 which is connected between the node nd45 and the ground voltage VSS and operates as a pull-down device pull-down driving the node nd45 in response to the second inverted FX signal FXB<m-1>. A second sub word line signal SWL<n, m-1> is outputted through the node nd45.

The sub word line driving circuit in accordance with the present embodiment is characterized in that the third FX driver 40 and the fourth FX driver 41 share the switching unit 42. As such, the sub word line driving circuit in accordance with the present embodiment can be realized with a less area compared to the sub word line driving circuits shown in FIGS. 3 and 5 since a leakage current flowing through the third FX driver 40 and the fourth FX driver 41 in a standby state can be reduced through one switching unit 42. Therefore, a layout burden of the sub word line driving circuit generated by adding the switching unit 42 can be reduced. If necessary, the sub word line driving circuit can be realized so that a plurality of FX drivers share one switching unit.

An operation of the sub word line driving circuit configured as described above will be described.

When the first inverted FX signal FXB<m> and the main word line signal MWLB<n> are enabled to a low level by decoding the row address, the third FX driver 40 receives the first inverted FX signal FXB<m> and drives a first FX signal FX<m> to a high level, and the third sub word line driver 43 drives the first sub word line signal SUB<n,m>. At this time, since the inverted bit line equalizing signal BLEQB is at a high level and the bit line equalizing signal BLEQ is at a low level, the NMOS transistor N42 is turned on to drive the node nd42 to the ground voltage VSS and the NMOS transistor N45 is turned off.

Next, when the first inverted FX signal FXB<m> and the inverted main word line signal MWLB<n> are shifted to a high level and a certain period is elapsed, the circuit is entered into the standby state. In the standby state, the NMOS transistor N42 is turned off since the inverted bit line equalizing signal BLEQB is at a low level. Therefore, the first FX signal FX<m> is not driven to the ground voltage VSS even when the NMOS transistor N40 is turned on by the first inverted FX signal FXB<m> at a high level. That is to say, the node nd40 through which the first FX signal FX<m> is outputted becomes a floating state and the node nd40 comes to have a raised level by a leakage current flowing through the PMOS transistor P42. Therefore, a voltage difference between gate and source of the PMOS transistor P42 is reduced and a leakage current flowing from the PMOS transistor P42 to the NMOS transistor N40, or GIDL is reduced.

Meanwhile, when the second inverted FX signal FXB<m-1> and the inverted main word line signal MWLB<n> are shifted to a high level and a certain period is elapsed, the circuit is entered into the standby state. In the standby state, the NMOS transistor N42 is turned off since the inverted bit line equalizing signal BLEQB is at a low level. Therefore, the second FX signal FX<m-1> is not driven to the ground voltage VSS even when the NMOS transistor N41 is turned on by the second inverted FX signal FXB<m-1> at a high level. That is to say, the node nd41 through which the second FX signal FX<m-1> is outputted comes to have a raised level by a leakage current flowing through the PMOS transistor P43. Also, the NMOS transistor N45 is turned on to drive the second FX signal FX<m-1> to the bit line precharge voltage VBLP since the bit line equalizing signal BLEQ is at a high level in the standby state. Therefore, a voltage difference between gate and source of the PMOS transistor P43 is reduced and a leakage current flowing from the PMOS transistor P43 to the NMOS transistor N41, or GIDL is reduced.

The inverted bit line equalizing signal BLEQB is shifted to a high level to turn off the NMOS transistor N42 a t1 period before the first inverted FX signal FXB<m> and the inverted main word line signal MWLB<n> are enabled again to a low level or the second inverted FX signal FXB<m-1> and the inverted main word line signal MWLB<n> are enabled again to a low level. Therefore, the node nd41 is driven to the ground voltage VSS to allow the first sub word line signal SWL<n,m> and the second sub word line signal SWL<n,m-1> to be sufficiently driven. At this time, the NMOS transistor N45 is turned off by the bit line equalizing signal BLEQ at a low level.

As such, the sub word line driving circuit in accordance with the present embodiment reduces the GIDL in the standby state by setting the node nd42 to a level higher than the ground voltage VSS by the bit line equalizing signal BLEQ and the inverted bit line equalizing signal BLEQB. Also, the sub word line driving circuit in accordance with the present embodiment allows the first sub word line signal SWL<n,m> and the second sub word line signal SWL<n,m-1> to be sufficiently driven by driving the node nd42 to the ground voltage VSS by the inverted bit line equalizing signal BLEQB before the first inverted FX signal FXB<m> and the inverted main word line signal MWLB<n> are shifted again to a low level or the second inverted FX signal FXB<m-1> and the inverted main word line signal MWLB<n> are enabled again to a low level. Further, in the sub word line driving circuit in accordance with the present embodiment, a leakage current flowing through the third FX driver 40 and the fourth FX driver 41 in a standby state can be reduced through one switching unit 42 and therefore a layout burden of the sub word line driving circuit generated by adding the switching unit 42 can be reduced.

While the present invention has been described with respect to the specific embodiments, it will be apparent to those skilled in the art that various changes and modifications may be made without departing from the spirit and scope of the invention as defined in the following claims.

The present application claims priority to Korean application number 10-2008-0132698, filed on Dec. 23, 2008, which is incorporated by reference in its entirety.

What is claimed is:

1. A sub word line driving circuit, comprising:
a FX driver which buffers an inverted FX signal and generates a FX signal in response to a control signal; and
a sub word line driver which is supplied with the FX signal and receives a main word line signal to drive a sub word line signal.

2. The sub word line driving circuit of claim 1, wherein the control signal is a bit line equalizing signal for precharging a bit line.

3. The sub word line driving circuit of claim 1, wherein the FX driver includes:
a pull-up device which is connected between a power voltage and a first node and pull-up drives the first node in response to the inverted FX signal;
a pull-down device which is connected between the first node and a second node and pull-down drives the first node in response to the inverted FX signal; and
a switching device which is connected between the second node and a ground voltage and is turned on in response to the control signal.

4. The sub word line driving circuit of claim 3, wherein the power voltage is a high voltage.

5. The sub word line driving circuit of claim 3, wherein the pull-up device is a PMOS transistor, and the pull-down device and the switching device are NMOS transistors.

6. The sub word line driving circuit of claim 1, wherein the sub word line driver includes:
a pull-up device which is connected between an input node for the FX signal and a first node and pull-up drives the first node in response to an inverted main word line signal; and
a first pull-down device which is connected between the first node and a ground voltage and pull-down drives the first node in response to the inverted main word line signal.

7. The sub word line driving circuit of claim 6, wherein the sub word line driver further includes a second pull-down device which is connected between the first node and a ground voltage and pull-down drives the first node in response to the inverted FX signal.

8. A sub word line driving circuit, comprising:
a FX driver which buffers an inverted FX signal and generates a FX signal in response to a control signal; and
a sub word line driver which is supplied with the FX signal, receives a main word line signal and drives a sub word line signal in response to the control signal.

9. The sub word line driving circuit of claim 8, wherein the control signal is a bit line equalizing signal which controls supply of a bit line precharge voltage to a bit line.

10. The sub word line driving circuit of claim 8, wherein the FX driver includes:
a pull-up device which is connected between a power voltage and a first node and pull-up drives the first node in response to the inverted FX signal;
a pull-down device which is connected between the first node and a second node and pull-down drives the first node in response to the inverted FX signal; and
a switching device which is connected between the second node and a ground voltage and is turned on in response to the control signal.

11. The sub word line driving circuit of claim 10, wherein the power voltage is a high voltage.

12. The sub word line driving circuit of claim 10, wherein the pull-up device is a PMOS transistor, and the pull-down device and the switching device are NMOS transistors.

13. The sub word line driving circuit of claim 8, wherein the sub word line driver includes:
a switching device which is connected between a power voltage and an input node for the FX signal and is turned on in response to the control signal;
a pull-up device which is connected between the input node for the FX signal and a first node and pull-up drives the first node in response to an inverted main word line signal; and
a first pull-down device which is connected between the first node and a ground voltage and pull-down drives the first node in response to the inverted main word line signal.

14. The sub word line driving circuit of claim 13, wherein the power voltage is a bit line precharge voltage and the control signal is a bit line equalizing signal which controls supply of a bit line precharge voltage to a bit line.

15. A sub word line driving circuit, comprising:
a first FX driver which is connected to a first node, buffers a first inverted FX signal and generates a first FX signal;
a second FX driver which is connected to the first node, buffers a second inverted FX signal and generates a second FX signal;
a first switching unit which is connected between the first node and a ground voltage and is turned on in response to a control signal;
a first sub word line driver which is supplied with the first FX signal and receives a main word line signal to drive a first sub word line signal; and
a second sub word line driver which is supplied with the second FX signal, receives the main word line signal and drives a second sub word line signal.

16. The sub word line driving circuit of claim 15, wherein the control signal is a bit line equalizing signal for precharging a bit line.

17. The sub word line driving circuit of claim 15, wherein the first FX driver includes:
a pull-up device which is connected between a power voltage and a second node and pull-up drives the second node in response to the first inverted FX signal; and
a pull-down device which is connected between the second node and the ground voltage and pull-down drives the second node in response to the first inverted FX signal.

18. The sub word line driving circuit of claim 17, wherein the power voltage is a high voltage.

19. The sub word line driving circuit of claim 15, wherein the second FX driver includes:
a pull-up device which is connected between a power voltage and a second node and pull-up drives the second node in response to the second inverted FX signal; and
a pull-down device which is connected between the second node and the ground voltage and pull-down drives the second node in response to the second inverted FX signal.

20. The sub word line driving circuit of claim 19, wherein the power voltage is a high voltage.

21. The sub word line driving circuit of claim 15, wherein the first sub word line driver includes:
a pull-up device which is connected between an input node for the FX signal and a second node and pull-up drives the second node in response to an inverted main word line signal; and
a first pull-down device which is connected between the second node and a ground voltage and pull-down drives the second node in response to the inverted main word line signal.

22. The sub word line driving circuit of claim 15, wherein the second sub word line driver includes:
a second switching device which is connected between a power voltage and an input node for the second FX signal and is turned on in response to the control signal;
a pull-up device which is connected between the input node for the second FX signal and a second node and pull-up drives the second node in response to an inverted main word line signal; and
a first pull-down device which is connected between the second node and a ground voltage and pull-down drives the second node in response to the inverted main word line signal.

23. The sub word line driving circuit of claim 22, wherein the power voltage is a bit line precharge voltage and the control signal is a bit line equalizing signal which controls supply of a bit line precharge voltage to a bit line.
